(19) United States
(12) Patent Application Publication
(10) Pub. No.: US 2015/0279686 A1
(43) Pub. Date: Oct. 1, 2015

(54) SEMICONDUCTOR PROCESSING METHODS

(71) Applicant: Taiwan Semiconductor Manufacturing Company Limited, Hsin-Chu (TW)

(72) Inventors: Cheng-Yu Kuo, Zhudong Township (TW); Teng-Chun Tsai, Hsinchu City (TW); Ying-Ho Chen, Taipei (TW); Kuo-Min Lin, Taichung City (TW); Ying-Tsung Chen, Hsinchu City (TW); Bing-Hung Chen, San-Xia Town (TW)

(21) Appl. No.: 14/230,178

(22) Filed: Mar. 31, 2014

(51) Int. Cl. H01L 21/311; H01L 21/66

(52) U.S. Cl. CPC H01L 21/31116; H01L 22/12

(57) ABSTRACT

One or more methods for semiconductor processing are provided. At least one of the methods include receiving information regarding a pre-etch back thickness of a first layer over a substrate, comparing the pre-etch back thickness to a desired thickness of the first layer, responsive to the pre-etch back thickness being greater than the desired thickness, determining parameters for an etch back process and performing the etch back process on the first layer to reduce the pre-etch back thickness to a first etch back thickness. The etch back process comprising performing a gas cluster ion beam etching process. In some embodiments, a second etch back process is performed. In some embodiments a wet clean process is performed on the first layer after the etch back process.

### BACKGROUND

During semiconductor processing, chemical mechanical planarization (CMP) is performed to smooth surfaces of one or more layers formed on a substrate using chemicals and/or mechanical forces. For example, a layer can be polished to prepare the layer for a new layer of material to be formed thereover or to prepare the layer for patterning. In one example of polishing, a semiconductor substrate such as a wafer is secured to a polishing head configured to hold and rotate the wafer. The polishing head rotates the wafer against a polishing pad, which also rotates in some situations, to apply mechanical force to the wafer or one or more layers formed thereon to remove material or even out irregular topography of or on the wafer. Chemicals, such as slurry, are at times applied to the polishing pad during polishing to serve as solvents which aid in reducing non-uniformities on the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for fabricating a semiconductor device, according to some embodiments;

FIG. 2 is a cross-sectional view of a semiconductor device during fabrication, according to some embodiments.

FIG. 3 is a cross-sectional view of a semiconductor device during fabrication, according to some embodiments.

FIG. 4 is a cross-sectional view of a semiconductor device during fabrication, according to some embodiments.

FIG. 5A is a cross-sectional view of a semiconductor device during fabrication, according to some embodiments.

FIG. 5B is a cross-sectional view of a semiconductor device during fabrication, according to some embodiments.

FIG. 5C is a cross-sectional view of a semiconductor device during fabrication, according to some embodiments.

FIG. 5D is a cross-sectional view of a semiconductor device during fabrication, according to some embodiments.

FIG. 6 is a cross-sectional view of a semiconductor device during fabrication, according to some embodiments.

FIG. 7 is a flow diagram illustrating a method for fabricating a semiconductor device, according to some embodiments.

FIG. 8 is an illustration of an example computer-readable medium comprising processor-executable instructions configured to embody one or more of the provisions set forth herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more semiconductor processing methods are provided herein. In some embodiments, a method includes an etch back process that utilizes a gas cluster ion beam etching process. In some embodiments, a thickness variation (variation) range of a resulting layer is less than about 100 angstroms across a wafer. In some embodiments, the variation range is less than about 30 angstroms across a wafer. In some embodiments, a wet clean process is provided. In some embodiments, the wet clean process removes or decreases surface defects and improves the uniformity of the layer.

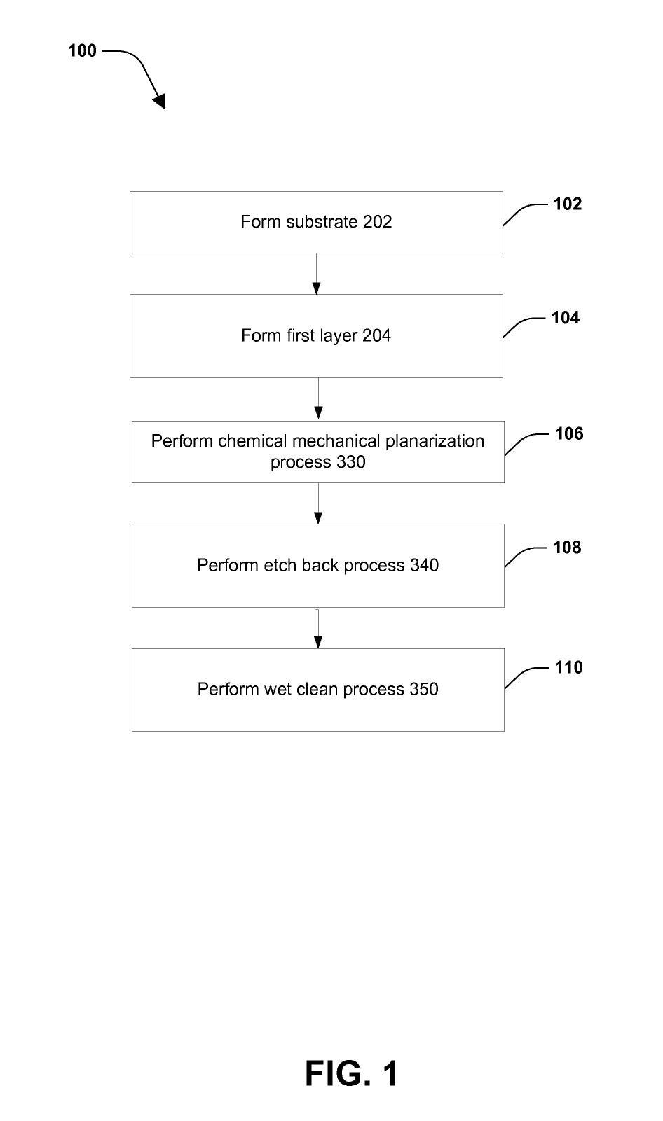

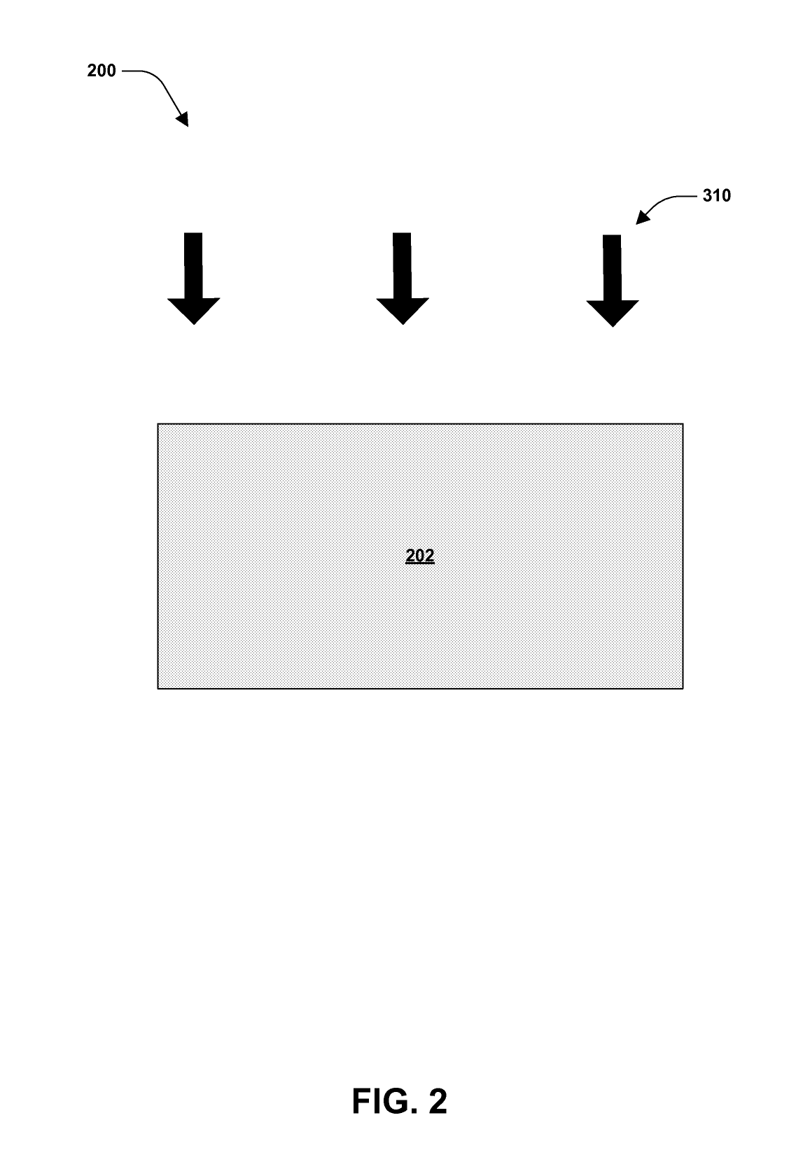

Referring to FIG. 1, illustrated is a flow diagram of a method 100 for semiconductor processing 200 according to some embodiments. Referring also to FIGS. 2 to 6, illustrated are cross-sectional views of the semiconductor device 200 at various stages of fabrication according to some embodiments, such as according to the method 100 of FIG. 1. In some embodiments, part of the semiconductor device 200 is fabricated with a CMOS process flow. In some embodiments, additional processes are provided before, during, and after the method 100 of FIG. 1.

At 102, a substrate 202 is formed, as illustrated in FIG. 2. In some embodiments, the substrate 202 is merely provided or received and is not formed as part of method 100. In some embodiments, the substrate 202 includes at least one of an epitaxial layer, a silicon-on-insulator (SOI) structure, a wafer, or a die formed from a wafer. In some embodiments, the substrate 202 is a silicon substrate. In some embodiments, the substrate 202 includes at least one of silicon germanium, silicon carbide, gallium arsenic, gallium phosphide, indium phosphide, indium arsenide, indium antimonide or other suitable semiconductor material. In some embodiments, the substrate 202 includes other features such as a buried layer or an epitaxy layer. In some embodiments, the substrate 202 includes a doped epi layer. In some embodiments, the substrate 202 includes a semiconductor layer overlying another semiconductor layer of a different type. In some embodiments, the substrate 202 is a silicon layer on a silicon germanium layer.

In some embodiments, at least some of the substrate 202 is formed or treated by a first process 310. In some embodiments, the first process 310 includes at least one of an epitaxy process, an implant process or a bonding process. In some embodiments, the substrate 202 is grown by at least one of solid-phase epitaxy (SPE) or vapor-phase epitaxy. In some embodiments, the first process 310 includes implanting a dopant. In some embodiments, the dopant is at least one of n-type or a p-type dopant. In some embodiments, the n-type dopant includes at least one of arsenic or phosphorous. In some embodiments, the p-type dopant includes boron. In some embodiments, the first process 310 includes a thermal process for dopant drive-in diffusion.

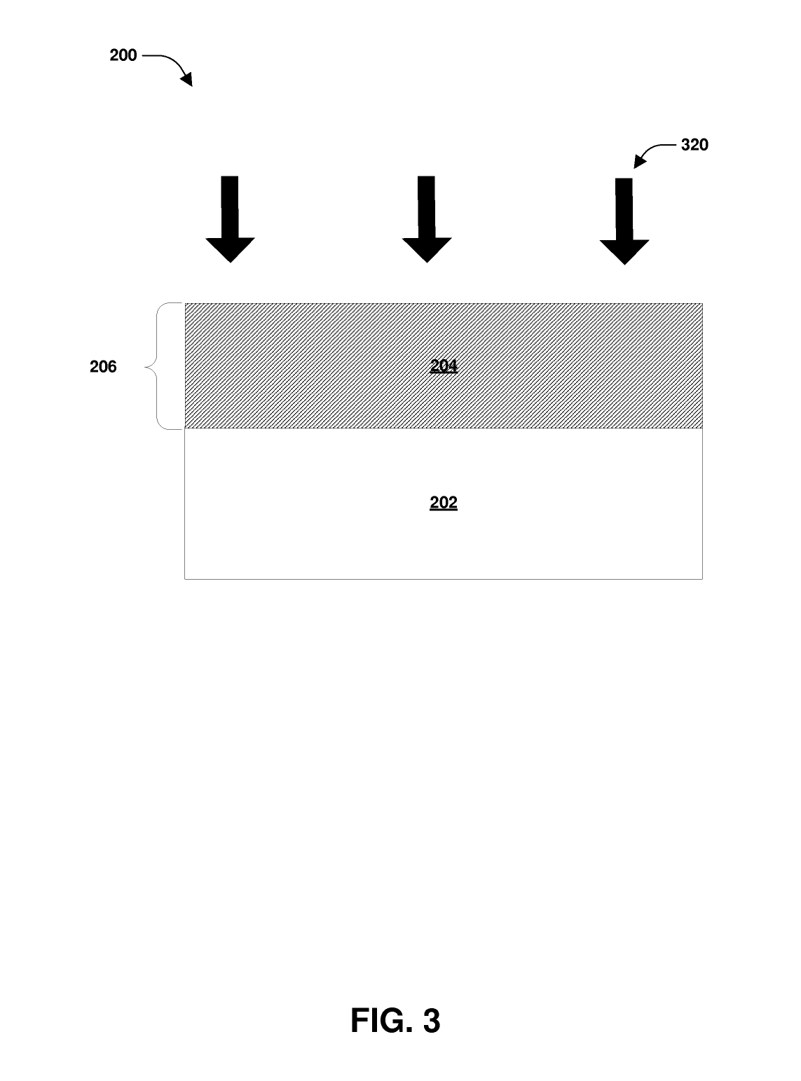

At 104, a first layer 204 is formed over the substrate 202, as illustrated in FIG. 3. In some embodiments, the first layer 204 is merely provided or received and is not formed as part of method 100. In some embodiments, the first layer 204 is at least one of a buried layer, a capping layer, a dielectric layer, an interfacial layer, a gate dielectric layer, an interlayer dielectric layer, a poly gate layer or a metal gate layer. In some embodiments, the first layer 204 includes a metal. In some embodiments, the first layer 204 includes at least one of aluminum (Al), copper (Cu), tungsten (W), titanium (Ti), tantalum (Ta), titanium nitride (TiN), titanium aluminide (TiAl), titanium aluminum nitride (TiAlN), tantalum nitride (TaN), nickel silicon (NiSi) or cobalt silicon (CoSi). In some embodiments, the first layer 204 includes a conductive material with a work function. In some embodiments, the first layer 204 includes a poly. In some embodiments, the poly is a poly-silicon. In some embodiments, first layer 204 includes a doped poly-silicon with at least one of uniform or non-uniform doping. In some embodiments, the first layer 204 is part of a gate stack (not illustrated).

In some embodiments, the first layer 204 is formed or treated by a second process 320. In some embodiments, the second process 320 utilizes at least one of an ALD, CVD, PVD or plating process. In some embodiments, the first layer 204 has a deposition thickness 206. In some embodiments, the deposition thickness 206 is between about 500 angstroms to about 5000 angstroms.

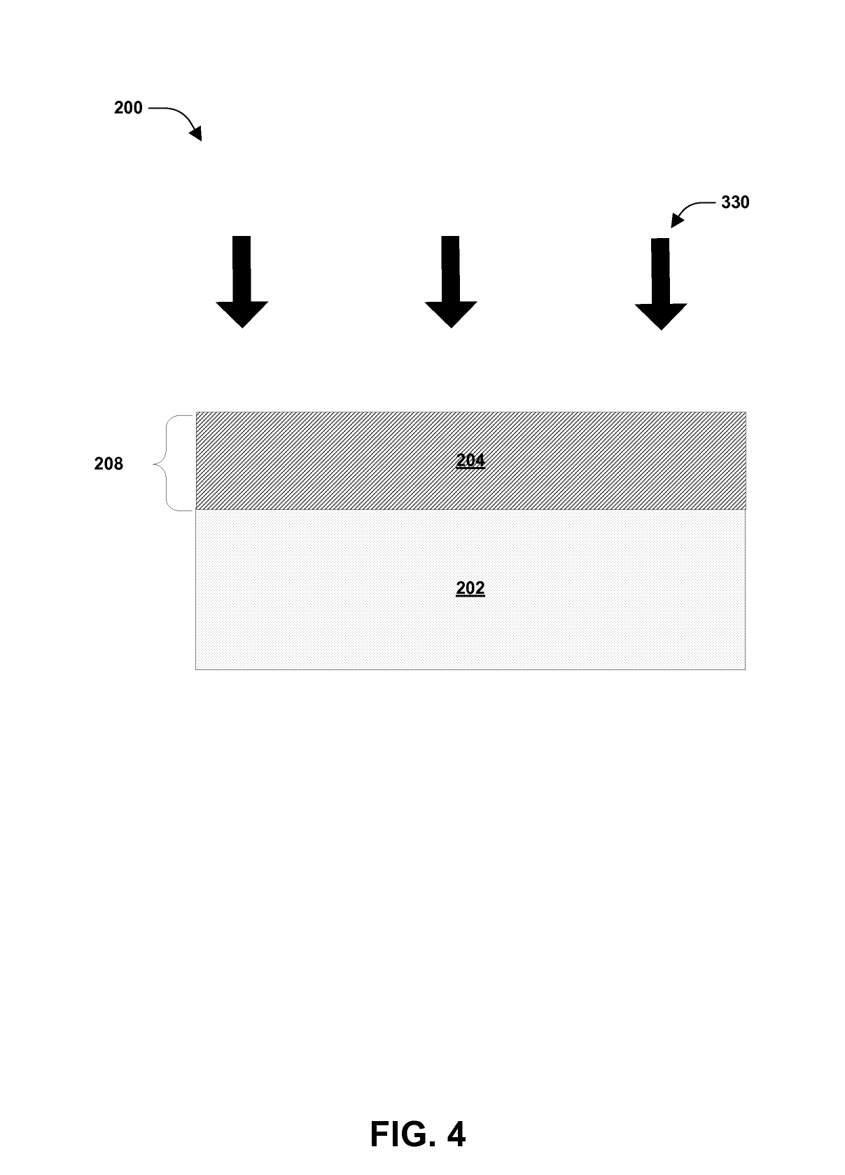

At 106, a chemical mechanical planarization (CMP) process 330 is performed on the first layer 204, as illustrated in FIG. 4. In some embodiments, the CMP process 330 includes polishing the first layer 204 with a chemical slurry in conjunction with a polishing pad. In some embodiments, the semiconductor device 200 is secured to a polishing head configure to hold and rotate the semiconductor device 200. In some embodiments, the CMP process 330 reduces the deposition thickness 206 to a CMP thickness 208. In some embodiments, the CMP thickness 208 is between about 300 angstroms to about 3000 angstroms.

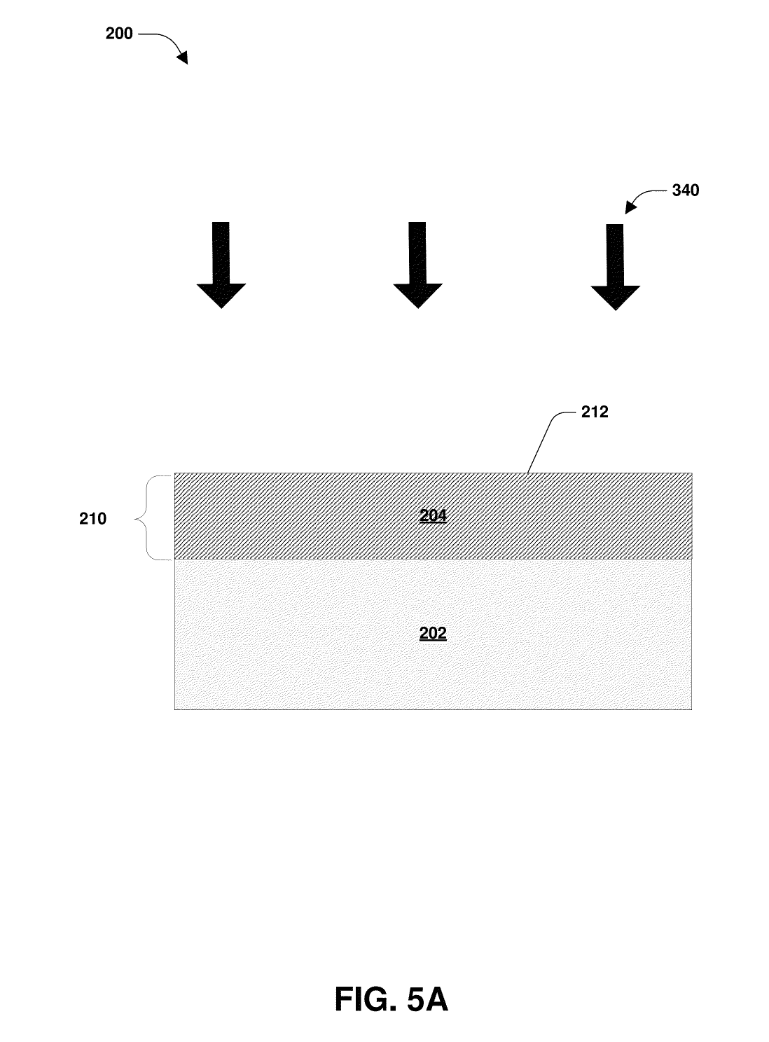

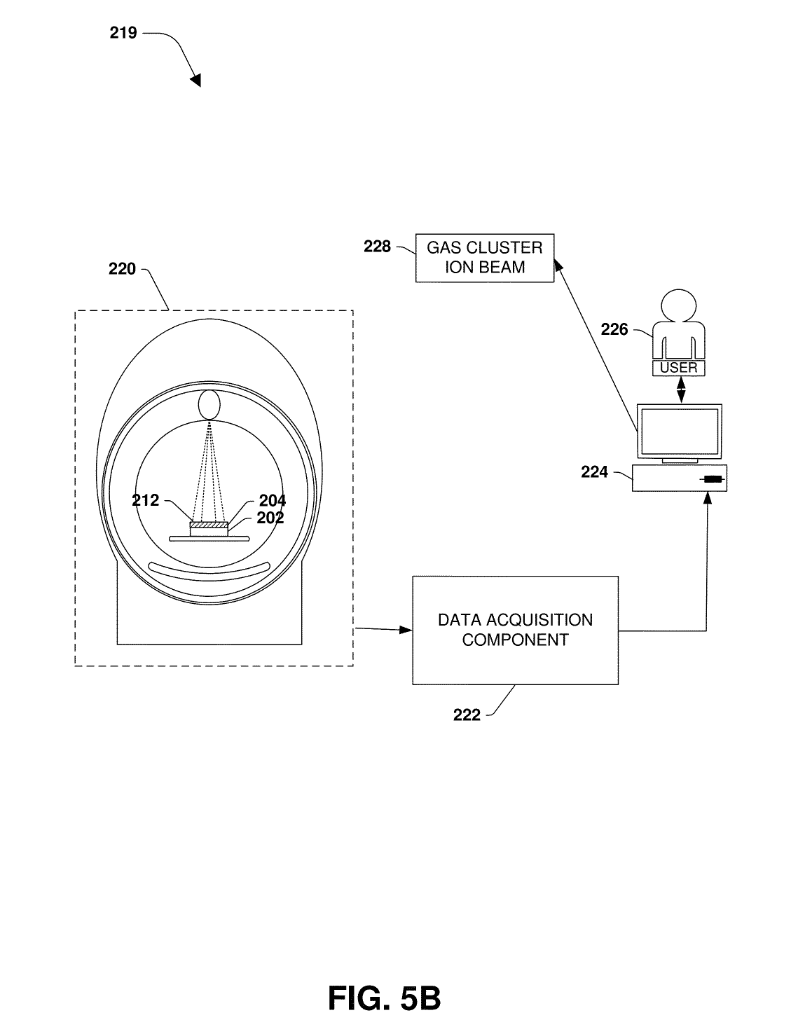

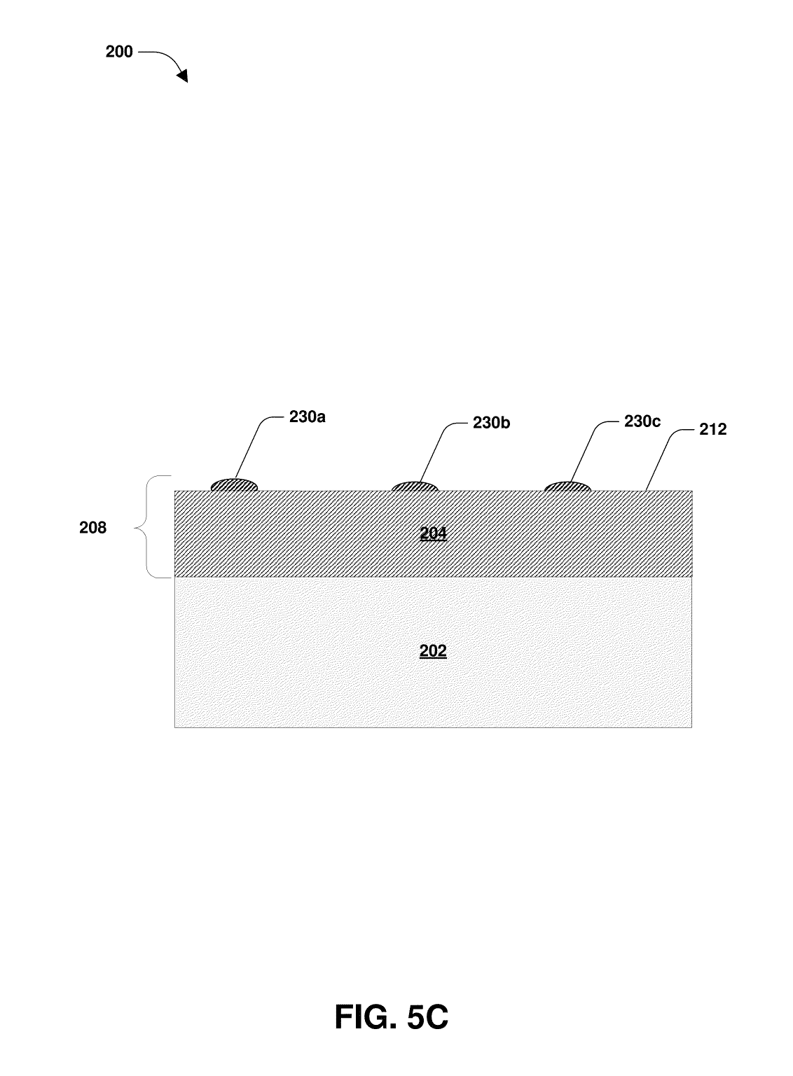

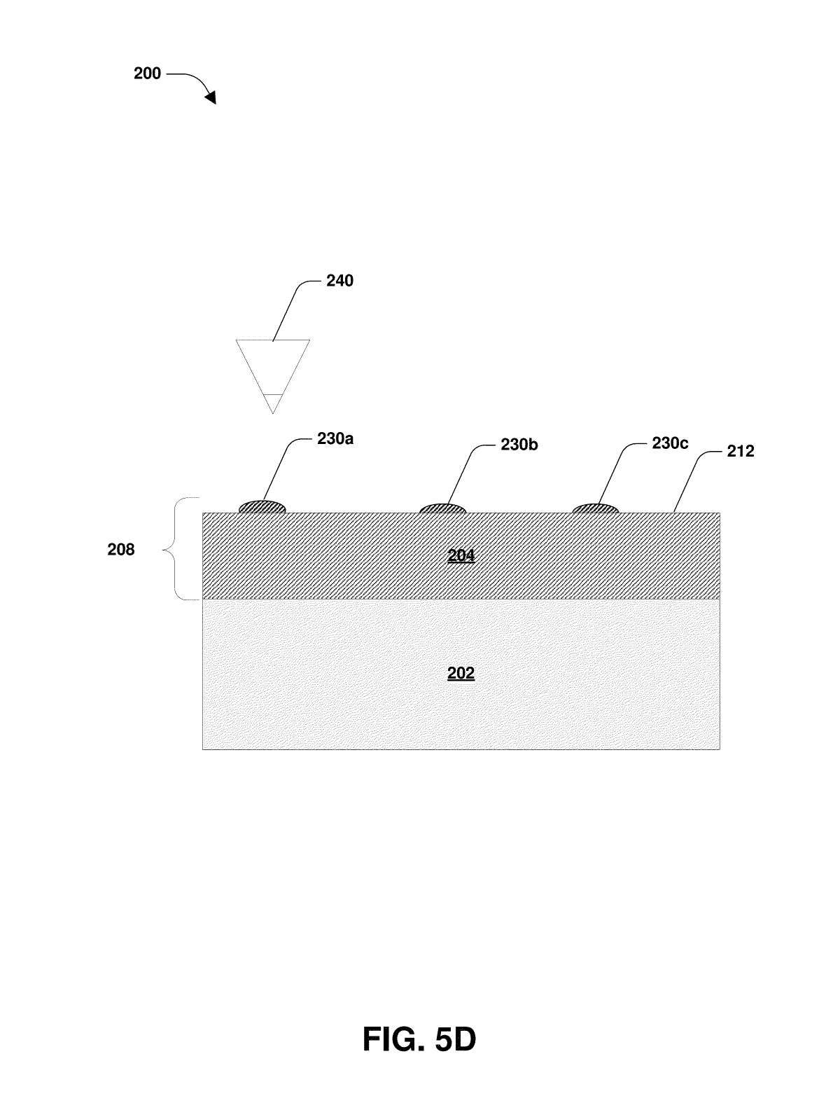

At 108, an etch back process 340 is performed on the first layer 204, as illustrated in FIG. 5a. In some embodiments, the etch back process 340 reduces a pre-etch back thickness to a first etch back thickness 210. In some embodiments, the pre-etch back thickness is at least one of the CMP thickness 208 or the deposition thickness 206. In some embodiments, the first etch back thickness 210 is between about 200 angstroms to about 2000 angstroms. In some embodiments, the etch back process 340 provides better uniformity to the first layer 204 than the CMP process 330. In some embodiments, the first layer 204 has a variation range of less than about 100 angstroms after the etch back process 340.

In some embodiments, the etch back process 340 includes scanning the first layer 204 with the scanning device 220, which part of an environment 219, as illustrated in FIG. 5b. In some embodiments, the scanning device 220 provides information regarding the pre-etch back thickness at various locations on a wafer. In some embodiments, the information is provided to a data acquisition component 222. In some embodiments, the scanning device 220 provides information regarding a surface profile of the top surface 212 to at least one of a computer processor 224, a user 226 or a gas cluster ion beam apparatus 228. In some embodiments, the scanning device 220 is an optical scanning device. In some embodiments, the optical scanning device is at least one of an ultra violate scanning device, an x-ray scanning device or the like. In some embodiments, at least one of the environment 219 or the scanning device 220 is used to compare the pre-etch thickness to a desired thickness. In some embodiments, high points 230a-230c on the top surface 212 of the first layer 204 that are greater than the desired thickness are identified, as illustrated in FIG. 5c.

In some embodiments, the etch back process 340 includes performing a gas cluster ion beam (GCIB) etching process, as illustrated in FIG. 5d. In some embodiments, the GCIB etching process is configured to reduce the high points 230a-230c on the top surface 212 identified by the scanning apparatus 220. In some embodiments, the GCIB etching process includes parameters that are configurable to achieve at least one of the desired thickness or uniformity of the first layer 204. In some embodiments, the parameters include at least one of a composition of the gas cluster ion beam gas, a gas flow rate, a stagnation pressure, an ion cluster concentration, an ion cluster size, an ion cluster energy, an ion cluster dose, beam size or a movement of the substrate relative to a gas cluster ion beam 240.

In some embodiments, the gas cluster ion beam gas includes at least one of a reactive gas or a carrier gas. In some embodiments, the reactive gas includes at least one of SiF₄ NF₃, CF₄, NH₄, CHF₃, O₂, N₂ or Ar. In some embodiments, the reactive gas includes SiF4. In some embodiments, the carrier gas includes at least one of N, He, Ne, Ar, Kr, Xe, or Rn. In some embodiments, the composition of the gas cluster ion beam gas is configured based upon the composition of first layer 204. In some embodiments, when the first layer 204 includes silicon, the gas cluster ion beam gas also contains silicon. In some embodiments, when the first layer 204 includes a poly silicon, the gas cluster ion beam gas includes SiF₄.

In some embodiments, the GCIB etching process is configurable with an ion cluster dose of between about 1E¹³ to about 1E¹⁸ ion clusters/cm². In some embodiments, the GCIB etching process is configurable an ion cluster energy of between about 1 KV to about 200 KV. In some embodiments, the GCIB process is configurable with an ion cluster concentration of between about 100 molecules to about 10,000 molecules per cluster. In some embodiments, the beam size is configurable from about 5 mm to about 10 mm in diameter. In some embodiments, the movement of the substrate is configurable so as to target the high points 230a-230c on the top surface 212 of the first layer 204 with the gas cluster ion beam 240, as illustrated in FIG. 5d. In some embodiments, the high points 230a-230c on the top surface 212 are exposed to the GCIB for a longer period of time than points closer in thickness to the desired thickness. In some embodiments, the parameters of the GCIB etching process are configurable to smooth the top surface 212 of the first layer 204. In some embodiments, the first etch back thickness 210 has a variation range of less than about 100 angstroms. In some embodiments, the first etch back thickness 210 has a variation range of less than about 30 angstroms. In some embodiments, the variation range of the first layer 204 is decreased by about 2 to about 3.5 times after the etch back process 340.

In some embodiments, if the desired thickness is not reached, a second etch back process including a second gas cluster ion beam etching process is performed to reduce the first etch back thickness to a second etch back thickness. In some embodiments, the top surface 212 of the first layer 204 is scanned for a second time after the etch back process 340. In some embodiments, a second set of parameters is determined for the second etch back process responsive to the difference in the first etch back thickness and the desired thickness.

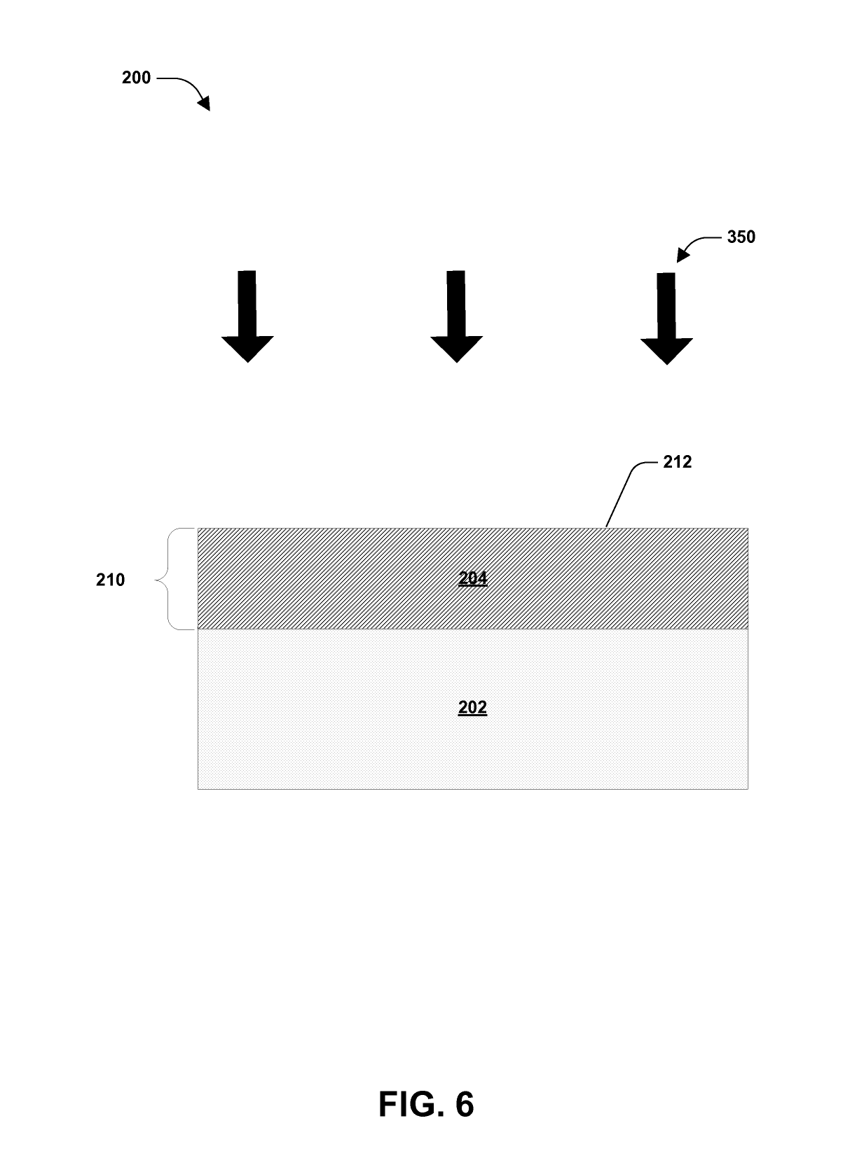

At 110, a wet clean process 350 is performed, as illustrated in FIG. 6. In some embodiments, the wet clean process 350 includes exposing at least part of the first layer 204 to a wash solution. In some embodiments, the wash solution includes at least one of hydrogen fluoride, ammonia or ozone. In some embodiments, the wash solution includes at least one of a hydrogen fluoride and ozone mixture (FOM) or an ammonia and ozone mixture (AOM). In some embodiments, the FOM contains about 1 to about 1000 ppm of ozone and between about 0.1% to about 5% of dihydrogen fluoride. In some embodiments, the FOM contains about 20 to about 40 ppm ozone and about 1.0% to about 2.0% dihydrogen fluoride. In some embodiments, the AOM contains about 1 to about 1000 ppm of ozone and about 0.1% to about 5% of ammonia. In some embodiments, the AOM contains about 20 to about 40 ppm ozone and about 1.0% to about 2.0% ammonia. In some embodiments, the wet clean process 350 includes exposing the first layer 204 to at least one of the FOM or the AOM. In some embodiments, the first layer 204 is exposed to at least one of the FOM or the AOM for about 5 to about 300 seconds. In some embodiments, the first layer 204 is exposed to the FOM for about 30 seconds and then exposed to the AOM for about 15 seconds. In some embodiments, the wet clean process 350 is performed 1 to 10 times. In some embodiments, the wet clean process 350 is performed at least 2 times.

In some embodiments, the wet clean process 350 is configured to smooth the top surface 212 and improve the uniformity of the first layer 204. In some embodiments, the wet clean process 350 removed or minimizes defects on the top surface 212 of the first layer 204. In some embodiments, the defects include at least one of particles, surface damage or scrum. In some embodiments, the wet clean process 350 reduces the variation range of the first etch back thickness 210 by between about 1 to about 100 angstroms.

In some embodiments, a patterning process is performed after the wet clean process 350.

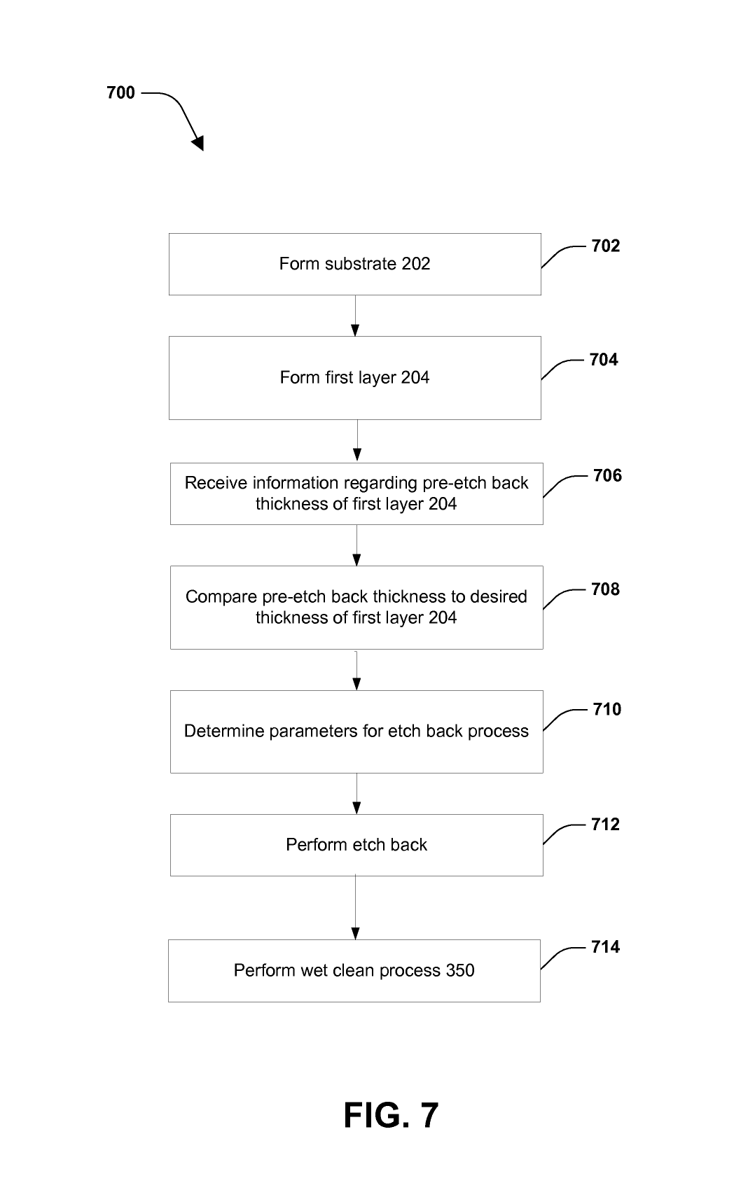

Referring to FIG. 7, illustrated is a flow diagram of a method 700 for fabricating a semiconductor device 200 according to some embodiments. In some embodiments, part of the semiconductor device 200 is fabricated with a CMOS process flow. In some embodiments, additional processes are provided before, during, and after the method 700 of FIG. 7. At 702, a substrate 202 is formed. In some embodiments, the substrate 202 is a wafer.

At 704, a first layer 204 is formed over the substrate 202. In some embodiments, the first layer 204 is at least one of a buried layer, a capping layer, a dielectric layer, an interfacial layer, a gate dielectric layer, an interlayer dielectric layer, a poly gate layer or a metal gate layer. In some embodiments, the first layer 204 is planarized. In some embodiments, the first layer 204 is planarized by a chemical mechanical planarization process 330. In some embodiments, the first layer 204 has a pre-etch back thickness.

At 706, information is received regarding the pre-etch back thickness of the first layer 204. In some embodiments, the information includes a surface profile of the first layer 204. In some embodiments, the information corresponds to a surface scan of a top surface 212 of the first layer 204.

At 708, the pre-etch back thickness is compared to a desired thickness of the first layer 204. In some embodiments, high points on the top surface 212 are identified.

At 710, parameters for an etch back process are determined. In some embodiments, the parameters are determined in response to the difference between the pre-etch back thickness and the desired thickness of the first layer 204. In some embodiments, determining the parameters includes determining at least one of a composition of a reactive gas, a composition of a carrier gas, an ion cluster dose, an ion cluster energy, an ion cluster concentration, beam size or a movement of the substrate relative to a gas cluster ion beam.

At 712, the etch back process 340 is performed on the first layer 204. In some embodiments, the etch back process includes performing a gas cluster ion beam etching process. In some embodiments, the etch back process 340 reduces the pre-etch back thickness to a first etch back thickness 210. In some embodiments, the first etch back thickness 210 is the desired thickness. In some embodiments, the first etch back thickness 210 is not the desired thickness and a second etch back process is performed on the first layer 204.

At 714, wet clean process 350 is performed. In some embodiments, the wet clean process 350 includes exposing the first layer 204 to a wash solution. In some embodiments, the wash solution includes at least one of hydrogen fluoride, ammonia or ozone. In some embodiments, the wet clean process 350 is performed 1 to 10 times. In some embodiments, the wet clean process 350 is performed at least 2 times.

In some embodiments, a patterning process is performed after the wet clean process 350.

In some embodiments, the semiconductor device 200 includes other layers or features not specifically illustrated including at least one of an interlayer dielectric (ILD) layer, a contact, an interconnect or other suitable features. In some embodiments, other back end of line (BEOL) processes are preformed on the semiconductor device 200.

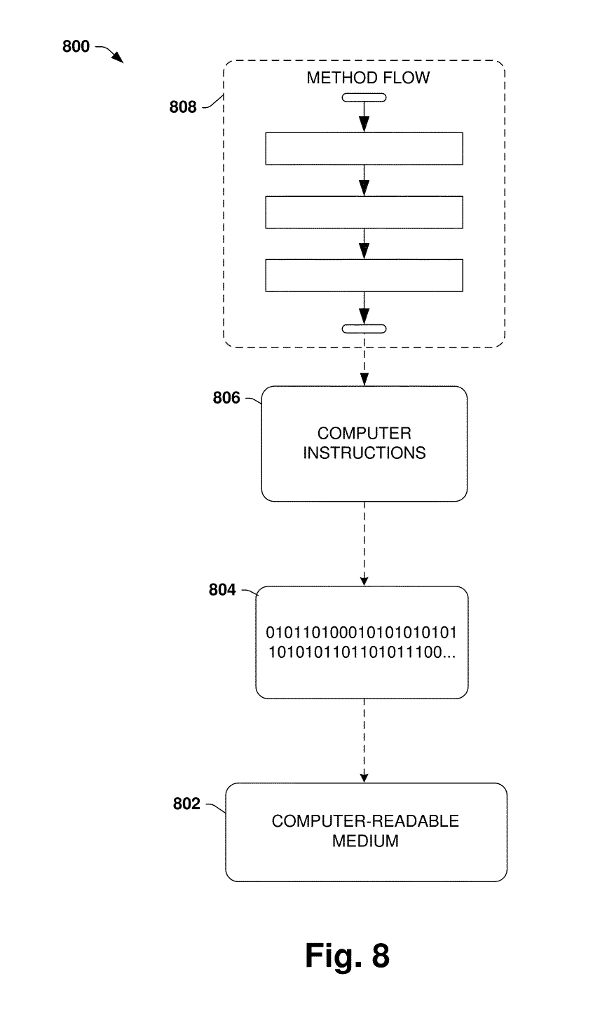

In some embodiments, a computer-readable medium comprising processor-executable instructions configured to implement one or more of the techniques presented herein. An example computer-readable medium is illustrated in FIG. 8, wherein the implementation 800 comprises a computer-readable medium 802 (e.g., a flash drive, CD-R, DVD-R, application-specific integrated circuit (ASIC), field-programmable gate array (FPGA), a platter of a hard disk drive, etc.), on which is encoded computer-readable data 804. This computer-readable data 804 in turn comprises a set of processor-executable instructions 806 configured to operate according to one or more of the principles set forth herein. In an embodiment 800, the processor-executable instructions 806 may be configured to perform an operation 808 when executed via a processing unit, such as at least some of the example method 100 of FIG. 1 or method 700 of FIG. 7. In an embodiment, the processor-executable instructions 806 may be configured to implement a system, such as at least some of the example method 100 of FIG. 1 or method 700 of FIG. 7. Many such computer-readable media may be devised by those of ordinary skill in the art that are configured to operate in accordance with one or more of the techniques presented herein.

According to some aspects of the instant disclosure, a method for semiconductor processing is provided. The method comprising forming a first layer over a substrate, the first layer having a pre-etch back thickness and performing an etch back process on the first layer to reduce the pre-etch back thickness to a first etch back thickness. The performing an etch back process comprising performing a gas cluster ion beam etching process.

According to some aspects of the instant disclosure, a method for semiconductor processing is provided. The method comprising receiving information regarding a pre-etch back thickness of a first layer over a substrate, comparing the pre-etch back thickness to a desired thickness of the first layer, responsive to the pre-etch back thickness being greater than the desired thickness, determining parameters for an etch back process and performing the etch back process on the first layer to reduce the pre-etch back thickness to a first etch back thickness. The performing an etch back process comprising performing a gas cluster ion beam etching process.

According to some aspects of the instant disclosure, a method for semiconductor processing is provided. The method comprising receiving information regarding a pre-etch back thickness of a first layer over a substrate, comparing the pre-etch back thickness to a desired thickness of the first layer based upon the information, responsive to the pre-etch back thickness being different than the desired thickness, determining parameters for a first etch back process, performing the first etch back process on the first layer according to the parameters to reduce the pre-etch back thickness to a first etch back thickness, receiving second information regarding the first etch back thickness of the first layer after the performing the first etch back process, comparing the first etch back thickness to the desired thickness based upon the second information, responsive to the first etch back thickness being different than the desired thickness, determining second parameters for a second etch back process, and performing the second etch back process on the first layer according to the second parameters to reduce the first etch back thickness to a second etch back thickness. The performing the first etch back process comprising performing a first gas cluster ion beam etching process. The performing the second etch back process comprising performing a second gas cluster ion beam etching process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Various operations of embodiments are provided herein. The order in which some or all of the operations are described should not be construed as to imply that these operations are necessarily order dependent. Alternative ordering will be appreciated given the benefit of this description. Further, it will be understood that not all operations are necessarily present in each embodiment provided herein. Also, it will be understood that not all operations are necessary in some embodiments.

Further, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel.

It will be appreciated that layers, features, elements, etc. depicted herein are illustrated with particular dimensions relative to one another, such as structural dimensions or orientations, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as implanting techniques, doping techniques, spin-on techniques, sputtering techniques, growth techniques, such as thermal growth or deposition techniques such as chemical vapor deposition (CVD), physical vapor deposition (PVD), plasma enhanced chemical vapor deposition (PECVD), or atomic layer deposition (ALD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B or the like generally means A or B or both A and B. Furthermore, to the extent that “includes”, “having”, “has”, “with”, or variants thereof are used in either the detailed description or the claims, such terms are intended to be inclusive in a manner similar to the term “comprising”.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method for semiconductor processing, comprising:
forming a first layer over a substrate, the first layer having a pre-etch back thickness; and
performing an etch back process on the first layer to reduce the pre-etch back thickness to a first etch back thickness, the performing an etch back process comprising:
performing a gas cluster ion beam etching process.

2. The method of claim 1, the performing a gas cluster ion beam etching process comprising:
exposing the first layer to a gas cluster ion beam gas comprising at least one of a reactive gas or a carrier gas.

3. The method of claim 2, the reactive gas comprising at least one of SiF₄ NF₃, CF₄, NH₄, CHF₃, O₂, N₂ or Ar.

4. The method of claim 2, the carrier gas comprising at least one of helium or nitrogen.

5. The method of claim 1, the performing a gas cluster ion beam etching process comprising:
performing the gas cluster ion beam etching process with an ion cluster dose of between about 1E¹³ ion clusters/cm² to about 1E¹⁸ ion clusters/cm².

6. The method of claim 1, the performing a gas cluster ion beam etching process comprising:
performing the gas cluster ion beam etching process with an ion cluster energy of between about 1 KV to about 200 KV.

7. The method of claim 1, the performing a gas cluster ion beam etching process comprising:
performing the gas cluster ion beam etching process with an ion cluster concentration of between about 100 molecules per cluster to about 10,000 molecules per cluster.

8. The method of claim 1, the first etch back thickness having a variation range of less than about 100 angstroms.

9. The method of claim 1, the first etch back thickness having a variation range of less than about 30 angstroms.

10. The method of claim 1, comprising:
performing a wet clean on the first layer after the performing a gas cluster ion beam etching process.

11. The method of claim 10, the performing a wet clean comprising:
exposing the first layer to at least one of a hydrogen fluoride and ozone mixture or an ammonia and ozone mixture.

12. The method of claim 1, the forming a first layer comprising:
performing at least one of plasma enhanced chemical vapor deposition (PECVD) process, a chemical vapor deposition (CVD) process or a spin-on process.

13. A method for semiconductor processing, comprising:
receiving information regarding a pre-etch back thickness of a first layer over a substrate;
comparing the pre-etch back thickness to a desired thickness of the first layer;
responsive to the pre-etch back thickness being greater than the desired thickness, determining parameters for an etch back process; and
performing the etch back process on the first layer to reduce the pre-etch back thickness to a first etch back thickness, the performing the etch back process comprising:
performing a gas cluster ion beam etching process.

14. The method of claim 13, the first etch back thickness having a variation range of less than about 100 angstroms.

15. The method of claim 13, the performing a gas cluster ion beam etching process comprising:
exposing the first layer to a gas cluster ion beam gas comprising at least one of a reactive gas or a carrier gas.

16. The method of claim 13, the determining parameters comprising determining at least one of a composition of gas cluster ion beam gas, a gas flow rate, a stagnation pressure, an ion cluster concentration, an ion cluster size, an ion cluster energy, an ion cluster dose, beam size or a movement of the substrate relative to a gas cluster ion beam.

17. The method of claim 13, the performing a gas cluster ion beam etching process comprising:
performing the gas cluster ion beam etching process with an ion cluster dose of between about 1E¹³ ion-clusters/cm² to about 1E¹⁸ ion-clusters/cm².

18. The method of claim 13, the performing a gas cluster ion beam etching process comprising:
performing the gas cluster ion beam etching process with an ion cluster energy of between about 1 KV to about 200 KV.

19. The method of claim 13, comprising:
performing a wet clean on the first layer after the performing a gas cluster ion beam etching process.

20. A method for semiconductor processing, comprising:
receiving information regarding a pre-etch back thickness of a first layer over a substrate;
comparing the pre-etch back thickness to a desired thickness of the first layer based upon the information;
responsive to the pre-etch back thickness being different than the desired thickness, determining parameters for a first etch back process;
performing the first etch back process on the first layer according to the parameters to reduce the pre-etch back thickness to a first etch back thickness, the performing the first etch back process comprising:
performing a first gas cluster ion beam etching process;
receiving second information regarding the first etch back thickness of the first layer after the performing the first etch back process;
comparing the first etch back thickness to the desired thickness based upon the second information;
responsive to the first etch back thickness being different than the desired thickness, determining second parameters for a second etch back process; and
performing the second etch back process on the first layer according to the second parameters to reduce the first etch back thickness to a second etch back thickness, the performing the second etch back process comprising:
performing a second gas cluster ion beam etching process.
